(19) United States
(12) Patent Application Publication
(10) Pub. No.: US 2026/0239700 A1
(43) Pub. Date: Aug. 13, 2026

(54) SILICON CARBIDE SEMICONDUCTOR DEVICE

(71) Applicant: FUJI ELECTRIC CO., LTD., Kawasaki-shi (JP)

(72) Inventor: Keiji OKUMURA, Matsumoto-city (JP)

(73) Assignee: FUJI ELECTRIC CO., LTD., Kawasaki-shi (JP)

(21) Appl. No.: 19/633,874

(22) Filed: Mar. 30, 2026

Related U.S. Application Data
(63) Continuation of application No. PCT/JP2025/005472, filed on Feb. 18, 2025.

(30) Foreign Application Priority Data
Mar. 15, 2024 (JP) 2024-041760

(51) Int. Cl. H10D 62/832; H10D 30/66; H10D 62/10; H10D 62/60

(52) U.S. Cl. CPC H10D 62/8325; H10D 30/668; H10D 62/102; H10D 62/126; H10D 62/60

(57) ABSTRACT

A silicon carbide semiconductor device includes a silicon carbide semiconductor substrate of a first conductivity type, a first semiconductor layer of the first conductivity type, a pn parallel region having first column regions of the first conductivity type and second column regions of a second conductivity type that repeatedly alternate with each other, a second semiconductor layer of the second conductivity type, first semiconductor regions of the first conductivity type, second semiconductor regions of the second conductivity type, trenches, gate insulating films, gate electrodes, high-concentration regions of the second conductivity type provided at positions facing the trenches in a depth direction, connection regions of the second conductivity type selectively provided closer to the second semiconductor layer than are the high-concentration regions so as to be in contact with the high-concentration regions and the second semiconductor layer, first electrodes, and a second electrode.

### CROSS REFERENCE TO RELATED APPLICATIONS

This is a continuation application of International Application PCT/JP2025/005472 filed on Feb. 18, 2025, which claims priority from a Japanese Patent Application No. 2024-041760 filed on Mar. 15, 2024, the contents of which are incorporated herein by reference.

### BACKGROUND OF THE INVENTION

### 1. Field of the Invention

Embodiments of the disclosure relate to a silicon carbide semiconductor device.

### 2. Description of the Related Art

One conventionally known semiconductor device has a carrier transport layer of a first conductivity type; an implantation control region of a second conductivity type, provided at an upper surface of the carrier transport layer; upper embedded regions of the second conductivity type in contact with a lower surface of the implantation control region; and lower embedded regions of the second conductivity type, respectively, in contact with lower surfaces of the upper embedded regions and bottom surfaces of trenches, the lower embedded regions being apart from each other via the carrier transport layer between the trenches (for example, refer to International Publication No. WO 2022/137789). In addition, one conventionally known superjunction silicon carbide semiconductor device has a lower p-type column region and an upper p-type column region that are provided so as to intersect with each other, so that even if pattern misalignment occurs, variation of on-resistance is eliminated and variation in performance may be suppressed (for example, refer to Japanese Patent No. 7293750).

### SUMMARY OF THE INVENTION

According to an embodiment of the disclosure, a semiconductor device, includes: a silicon carbide semiconductor substrate of a first conductivity type, having a front surface and a back surface; a first semiconductor layer of the first conductivity type, provided on the front surface of the silicon carbide semiconductor substrate and having a dopant concentration lower than a dopant concentration of the silicon carbide semiconductor substrate, the first semiconductor layer having a first surface and a second surface opposite to each other, the second surface facing the silicon carbide semiconductor substrate; a pn parallel region provided at the first surface of the first semiconductor layer, and having a plurality of first column regions of the first conductivity type and a plurality of second column regions of a second conductivity type disposed repeatedly alternating with each other in a plane parallel to the front surface of the silicon carbide semiconductor substrate; a second semiconductor layer of a second conductivity type, provided at the first surface of the first semiconductor layer and having a first surface and a second surface opposite to each other, the second surface thereof facing the silicon carbide semiconductor substrate; a plurality of first semiconductor regions of the first conductivity type, selectively provided in the second semiconductor layer, at the first surface thereof; a plurality of second semiconductor regions of the second conductivity type, selectively provided in the second semiconductor layer, at the first surface thereof, in contact with the plurality of first semiconductor regions and the second semiconductor layer; a plurality of trenches penetrating through the plurality of first semiconductor regions, respectively, and the second semiconductor layer, and reaching the first semiconductor layer; a plurality of gate insulating films, respectively, provided in the plurality of trenches; a plurality of gate electrodes, respectively, provided in the plurality of trenches via the plurality of gate insulating films; a plurality of high-concentration regions of the second conductivity type, provided in the first semiconductor layer, respectively, at positions facing the plurality of trenches in a depth direction of the semiconductor device; a plurality of connection regions of the second conductivity type, selectively provided in the first semiconductor layer, the plurality of connection regions being closer to the second semiconductor layer than are the plurality of high-concentration regions, and being closer to the silicon carbide semiconductor substrate than is the second semiconductor layer, the plurality of connection regions being in contact with the plurality of high-concentration regions and the second semiconductor layer; a plurality of first electrodes provided at surfaces of the plurality of the first semiconductor regions and the plurality of second semiconductor regions; a second electrode provided at the back surface of the silicon carbide semiconductor substrate. The plurality of second semiconductor regions is disposed periodically in a longitudinal direction of the plurality of trenches, and the plurality of connection regions is disposed periodically in the longitudinal direction of the plurality of trenches, in regions not overlapping the plurality of second semiconductor regions in a plan view of the semiconductor device.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a perspective view depicting a structure of a silicon carbide semiconductor device according to a first embodiment.

FIG. 2A is a cross-sectional view depicting the structure of the silicon carbide semiconductor device according to the first embodiment, along cutting line A-A′ in FIG. 1.

FIG. 2B is a cross-sectional view depicting the structure of the silicon carbide semiconductor device according to the first embodiment, along line cutting B-B′ in FIG. 1.

FIG. 2C is a cross-sectional view depicting the structure of the silicon carbide semiconductor device according to the first embodiment, along cutting line C-C′ in FIG. 1.

FIG. 2D is a cross-sectional view depicting another structure of the silicon carbide semiconductor device according to the first embodiment, along cutting line C-C′ in FIG. 1.

FIG. 3A is a plan view depicting the structure of the silicon carbide semiconductor device according to the first embodiment, at a depth D in FIGS. 2A to 2C.

FIG. 3B is a plan view depicting the structure of the silicon carbide semiconductor device according to the first embodiment, a depth E in FIGS. 2A to 2C.

FIG. 3C is a plan view depicting the structure of the silicon carbide semiconductor device according to the first embodiment, at a depth F in FIGS. 2A to 2C.

FIG. 3D is a plan view depicting the structure of the silicon carbide semiconductor device according to the first embodiment, at a depth G in FIGS. 2A to 2C.

FIG. 4 is a perspective view depicting a structure of a silicon carbide semiconductor device according to a second embodiment.

FIG. 5 is a cross-sectional view depicting the structure of the silicon carbide semiconductor device according to the second embodiment, along cutting line A-A′ in FIG. 4.

FIG. 6 is a plan view depicting the structure of the silicon carbide semiconductor device according to the second embodiment, along cutting line B-B′ in FIG. 5.

FIG. 7 is a perspective view depicting a structure of a silicon carbide semiconductor device according to a third embodiment.

FIG. 8 is a cross-sectional view depicting the structure of the silicon carbide semiconductor device according to the third embodiment, along cutting line A-A′ in FIG. 7.

FIG. 9 is a plan view depicting the structure of the silicon carbide semiconductor device according to the third embodiment, along cutting line B-B′ in FIG. 8.

FIG. 10 is a perspective view depicting a structure of a silicon carbide semiconductor device according to a fourth embodiment.

FIG. 11 is a cross-sectional view of the structure of the silicon carbide semiconductor device according to the fourth embodiment, along cutting line A-A′ in FIG. 10.

FIG. 12 is a cross-sectional view of the structure of the silicon carbide semiconductor device according to the fourth embodiment, along cutting line B-B′ in FIG. 10.

FIG. 13 is a plan view depicting the structure of the silicon carbide semiconductor device according to the fourth embodiment, along cutting line C-C′ in FIGS. 11 and 12.

FIG. 14 is a cross-sectional view depicting a structure of a silicon carbide semiconductor device of a comparative example, along cutting line A-A′ in FIG. 16.

FIG. 15 is a cross-sectional view depicting the structure of the silicon carbide semiconductor device of the comparative example, along cutting line B-B′ in FIG. 16.

FIG. 16 is a perspective view depicting the structure of the silicon carbide semiconductor device of the comparative example.

FIG. 17 is a characteristic diagram depicting a relationship between cell pitch and on-resistance of the silicon carbide semiconductor device according to the first embodiment.

### DETAILED DESCRIPTION OF THE INVENTION

First, problems associated with the conventional techniques are discussed. Regarding the structure of the conventional semiconductor device, since the structure of each cell is complicated, it is difficult to shorten the cell pitch. Therefore, it is difficult to reduce the resistance particularly in SiC, which as low channel mobility. Further, since the structure is complicated, the p-type region of the pn junction portion becomes thin, and there is a problem in that electric field tends to concentrate and the breakdown voltage decreases.

Here, an outline of an embodiment of the present disclosure will be described. A silicon carbide semiconductor device according to the disclosure has the following features. At a front surface of a silicon carbide semiconductor substrate of a first conductivity type, a first semiconductor layer of the first conductivity type and having a dopant concentration lower than that of the silicon carbide semiconductor substrate is provided. At a first surface of the first semiconductor layer, opposite to a second surface thereof facing the silicon carbide semiconductor substrate, a pn parallel region is provided having first column regions of the first conductivity type and second column regions of a second conductivity type repeatedly alternating with each other in a plane parallel to the front surface. At the first surface of the first semiconductor layer, a second semiconductor layer of the second conductivity type is provided. At a first surface of the second semiconductor layer, opposite to a second surface thereof facing the silicon carbide semiconductor substrate, first semiconductor regions of the first conductivity type are selectively provided. At the first surface of the second semiconductor layer, second semiconductor regions of the second conductivity type are provided in contact with the first semiconductor regions and the second semiconductor layer. Trenches penetrating through the first semiconductor regions and the second semiconductor layer and reaching the first semiconductor layer are provided. Gate electrodes are provided in the trenches via trench insulating films. In the first semiconductor layer, at positions facing the trenches in a depth direction, high-concentration regions of the second conductivity type are provided. In the first semiconductor layer, connection regions of the second conductivity type are selectively provided closer to the second semiconductor layer than are the high-concentration regions and closer to the silicon carbide semiconductor substrate than is the second semiconductor layer, the connection regions being in contact with the high-concentration regions and the second semiconductor layer. First electrodes are provided at surfaces of the first semiconductor regions and the second semiconductor regions. A second electrode is provided at a back surface of the silicon carbide semiconductor substrate. The second semiconductor regions are disposed periodically in a longitudinal direction of the trenches and the connection regions are disposed periodically in the longitudinal direction of the trenches, in regions not overlapping the second semiconductor regions in a plan view.

Here, findings underlying the present disclosure are discussed. First, problems related to a semiconductor device of a comparative example will be described. Silicon carbide (SiC) is expected as a next-generation semiconductor material to replace silicon (Si). A semiconductor device using silicon carbide as a semiconductor material (hereinafter referred to as a silicon carbide semiconductor device) has various advantages over a conventional semiconductor device using silicon as a semiconductor material. For example, the resistance of the device in an on-state may be reduced to several hundredths, and the device may be used in an environment at a higher temperature (200 degrees C. or higher). This is because the band gap of silicon carbide is about three times larger than that of silicon, and the dielectric breakdown electric field strength of silicon carbide is about one order of magnitude larger than that of silicon.

So far, as silicon carbide semiconductor devices, Schottky barrier diodes (SBDs) and vertical metal oxide semiconductor field effect transistors (MOSFETs) having a planar gate structure or a trench gate structure have been commercialized.

A planar gate structure is a MOS gate structure in which a planar MOS gate is provided at the front surface of a semiconductor substrate. A trench gate structure is a MOS gate structure in which a MOS gate is embedded in a trench formed at the front surface of a semiconductor substrate (semiconductor chip), and a channel (inversion layer) is formed in a direction orthogonal to the front surface of the semiconductor substrate along sidewalls of the trench. Therefore, as compared with a planar gate structure in which a channel is formed along the front surface of the semiconductor substrate, the unit cell (constituent unit of the device) density per unit area may be increased, and the current density per unit area may be increased, which is advantageous in terms of cost.

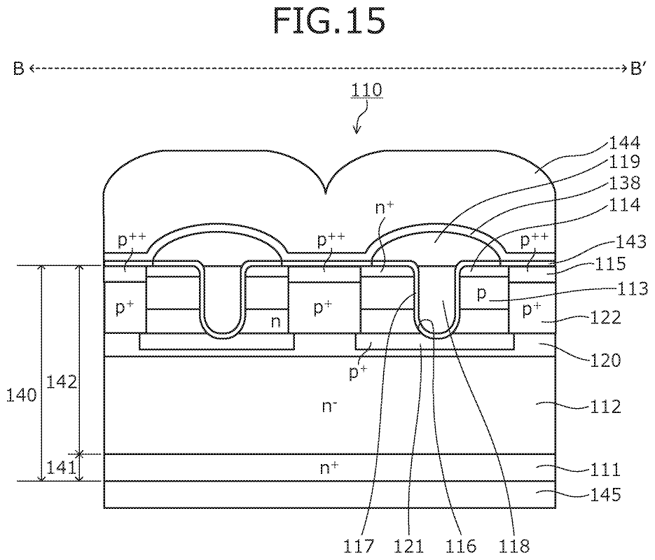

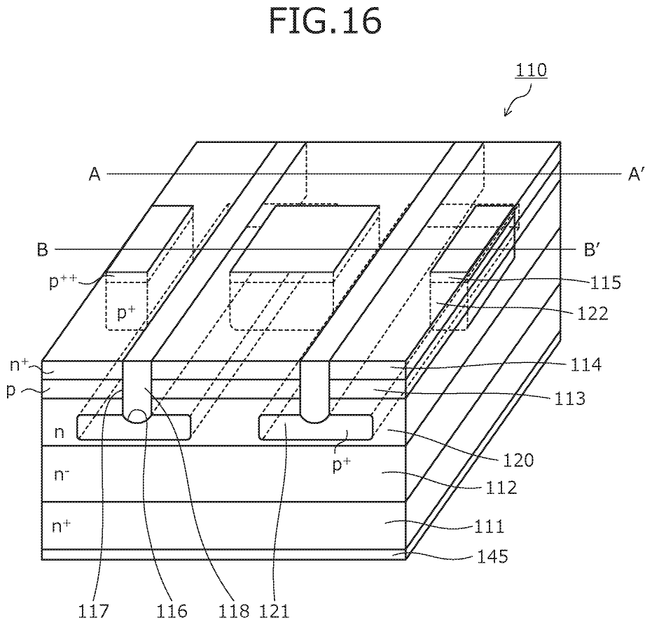

FIG. 14 is a cross-sectional view depicting the structure of the silicon carbide semiconductor device of the comparative example, along cutting line A-A′ in FIG. 16. FIG. 15 is a cross-sectional view depicting the structure of the silicon carbide semiconductor device of the comparative example, along cutting line B-B′ in FIG. 16. FIG. 16 is a perspective view depicting the structure of the silicon carbide semiconductor device of the comparative example. A semiconductor device 110 of the comparative example depicted in FIGS. 14 to 16 is a vertical MOSFET having a trench gate structure in a semiconductor substrate (semiconductor chip) 140 containing silicon carbide. In FIGS. 14 to 16, only an active region is depicted while an edge termination region is not depicted.

The semiconductor substrate 140 is formed by growing, by epitaxy, an n⁻-type silicon carbide layer 142 constituting an n⁻-type drift region 112, on a front surface of an n⁺-type starting substrate 141 containing silicon carbide. The semiconductor substrate 140 has, as a front surface, a main surface having the n⁻-type silicon carbide layer 142 and as a back surface, a main surface having the n⁺-type starting substrate 141. A drain electrode 145 is provided on an entire area of the back surface of the semiconductor substrate 140 (back surface of the n⁺-type starting substrate 141). The n⁺-type starting substrate 141 constitutes the n⁺-type drain region 111.

An n-type current spreading region 120 is provided at a first surface of the n⁻-type drift region 112, opposite to a second surface thereof facing the n⁺-type silicon carbide substrate 111. In the n-type current spreading region 120, p⁺-type regions 121 are selectively provided, respectively, at positions facing bottoms of trenches 116 in a depth direction. The MOS gates having a trench gate structure have a p-type base region 113, an n⁺-type source region 114, p⁺⁺-type contact regions 115, the trenches 116, a gate insulating film 117, and gate electrodes 118. below the p⁺⁺-type contact regions 115, p⁺-type regions 122 are selectively provided.

An interlayer insulating film 119 is provided on the gate electrodes 118, and an ohmic electrode 143 in contact with the n⁺-type source region 114 and the p⁺⁺-type contact regions 115 is provided in openings of the interlayer insulating film 119. A barrier metal 138 for preventing diffusion of metal atoms toward the gate electrodes 118 is provided on the ohmic electrode 143 and the interlayer insulating film 119. A source electrode 144 is provided on the barrier metal 138.

The p⁺-type regions 121 and 122 are fixed to the potential of the source electrode 144, and have a function of relaxing the electric field applied to the gate insulating film 117 by being depleted (and/or depleting the n-type current spreading region 120) when the MOSFET (silicon carbide semiconductor device 110) is off. The p⁺-type regions 121 are provided apart from the p-type base region 113 and face the bottoms of the trenches 116 in the depth direction. The p⁺-type regions 121 are electrically connected to the source electrode 144 by being partially connected to the p⁺-type regions 122. FIG. 14 depicts a cross section of a portion where the p⁺-type regions 122 are not provided, and FIG. 15 depicts a cross section of a portion where the p⁺-type regions 122 are provided and the p⁺-type regions 122 and the p⁺-type regions 121 are connected to each other.

As described, the p⁺-type regions between the trenches 116, provided at the same depth as the p⁺-type regions 121 are eliminated, and the JFET structure of each cell (the structure of the portion where the current flows between the trenches 116) is uniform. Further, the connection between the p⁺-type regions 121 and the p⁺⁺-type contact regions 115 is realized by forming the deep p⁺-type regions 122 at a center between the trenches 116 adjacent to each other.

Thus, the cell pitch may be shortened by simplifying the structure of each cell, and the resistance of the SiC MOSFET, which has low channel mobility, may be reduced by shortening the cell pitch. Further, a margin is provided in the structure between the trenches 116, the width of the p⁺-type regions 121 below the trenches 116 may be widened, and a flat portion of the pn junction is widened, so that the electric field concentration may be relaxed and the breakdown voltage may be increased.

However, in this structure, a connection portion between the p⁺-type regions 121 below the trenches 116 and the p⁺-type regions 122 below the p⁺⁺-type contact regions 115 becomes thin. Therefore, when a high voltage is applied to the drain electrode 145 and the depletion region spreads, a neutral region of the p⁺-type regions 121 and a neutral region of the p⁺-type regions 122 are apart from each other, and the p⁺-type regions 121 are brought into an electrically floating state. As a result, there is a problem in that the feedback capacitance rapidly fluctuates, and an increase in SW (switching) loss due to this fluctuation occurs. In addition, since the p⁺-type regions 121 protecting the trenches 116 is electrically floated, a high voltage is applied to the gate insulating film 117. In addition, since the p-type base region 113, which is a channel region, has a wide region on the side exposed to the drain electrode 145, a high voltage is applied to the channel, resulting in a decrease in breakdown voltage.

Embodiments of a silicon carbide semiconductor device according to the present disclosure will be described in detail with reference to the accompanying drawings. In the present description and accompanying drawings, layers and regions prefixed with n or p mean that majority carriers are electrons or holes. Additionally, + or − appended to n or p means that the dopant concentration is higher or lower, respectively, than layers and regions without + or −. In the description of the embodiments below and the accompanying drawings, main portions that are identical will be given the same reference numerals and will not be repeatedly described. Further, with consideration of variation in manufacturing, description indicating the same or equal may be within 5%.

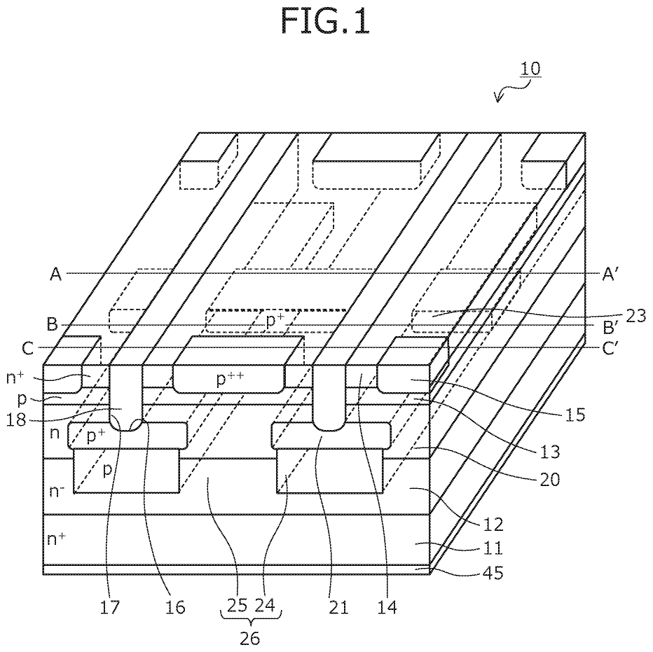

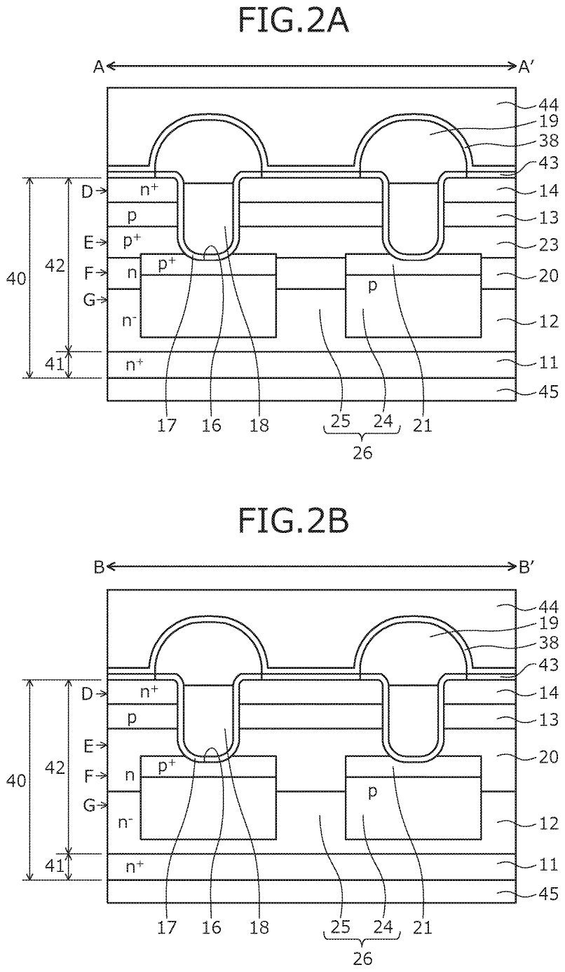

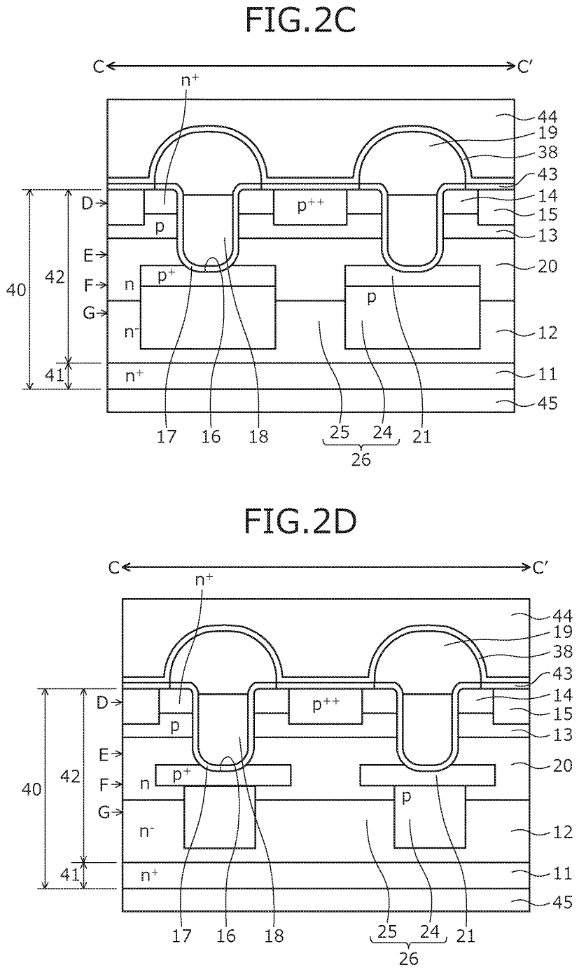

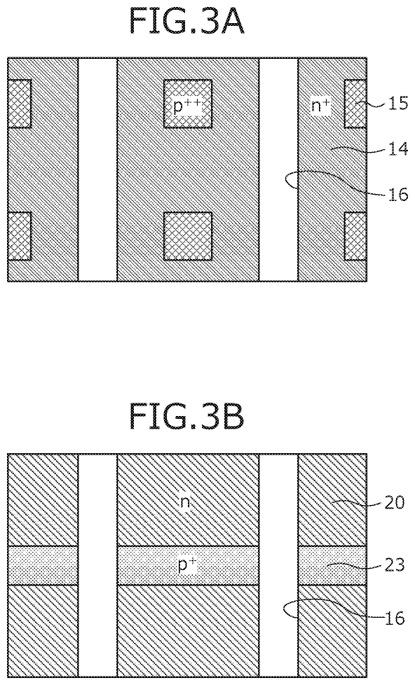

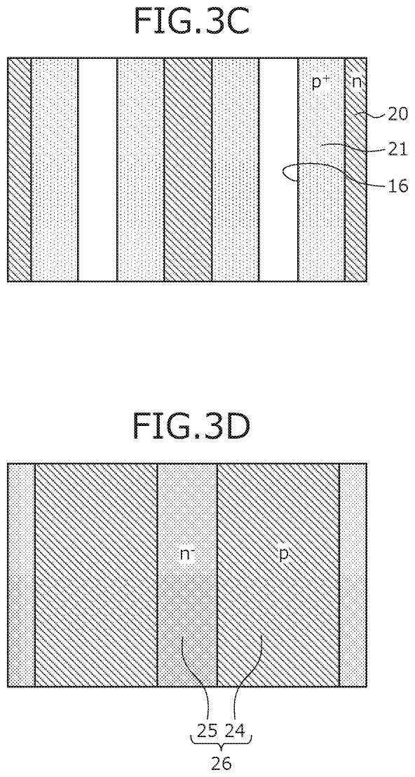

A structure of a silicon carbide semiconductor device according to a first embodiment will be described. FIG. 1 is a perspective view depicting the structure of the silicon carbide semiconductor device according to the first embodiment. FIG. 2A is a cross-sectional view depicting the structure of the silicon carbide semiconductor device according to the first embodiment, along cutting line A-A′ in FIG. 1. FIG. 2B is a cross-sectional view depicting the structure of the silicon carbide semiconductor device according to the first embodiment, along line cutting B-B′ in FIG. 1. FIG. 2C is a cross-sectional view depicting the structure of the silicon carbide semiconductor device according to the first embodiment, along cutting line C-C′ in FIG. 1. FIG. 2D is a cross-sectional view depicting another structure of the silicon carbide semiconductor device according to the first embodiment, along cutting line C-C′ in FIG. 1. FIG. 3A is a plan view depicting the structure of the silicon carbide semiconductor device according to the first embodiment, at a depth D in FIGS. 2A to 2C. FIG. 3B is a plan view depicting the structure of the silicon carbide semiconductor device according to the first embodiment, a depth E in FIGS. 2A to 2C. FIG. 3C is a plan view depicting the structure of the silicon carbide semiconductor device according to the first embodiment, at a depth F in FIGS. 2A to 2C. FIG. 3D is a plan view depicting the structure of the silicon carbide semiconductor device according to the first embodiment, at a depth G in FIGS. 2A to 2C. The silicon carbide semiconductor device 10 according to the first embodiment depicted in FIGS. 1 to 3D is a vertical MOSFET having a trench gate structure in a semiconductor substrate (semiconductor chip) 40 containing silicon carbide (SiC).

In FIGS. 1 to 3D, only an active region through which a current flows in an on-state is depicted, and an edge termination region which surrounds a periphery of the active region in a substantially rectangular shape in a plan view and in which a voltage withstanding structure is provided is not depicted. The voltage withstanding structure has a function of relaxing electric field in the vicinity of a boundary between the active region and the edge termination region, thereby sustaining the breakdown voltage. The breakdown voltage is a voltage limit at which breakdown does not occur even when a drain-source current increases due to avalanche breakdown occurring at a pn junction.

The semiconductor substrate 40 has multiple unit cells (functional units of the device) having the same MOSFET structure (element structure) adjacently arranged in parallel. The semiconductor substrate 40 is formed by growing, by epitaxy, an n⁻-type silicon carbide layer 42 constituting an n⁻-type drift region (first semiconductor layer of the first conductivity type) 12, on a front surface of an n⁺-type starting substrate (silicon carbide semiconductor substrate of the first conductivity type) 41 containing silicon carbide. The semiconductor substrate 40 has, as a front surface (first main surface), a main surface having the n⁻-type silicon carbide layer 42, and as a back surface (second main surface), a main surface having the n⁺-type starting substrate 41.

The n⁺-type starting substrate 41 constitutes an n⁺-type drain region 11. To form each portion of the active region, the semiconductor substrate 40 is grown by epitaxy in multiple stages on the n⁺-type starting substrate 41 sequentially from the n⁻-type silicon carbide layer 42 that constitutes an n⁻-type drift region 12. The n⁻-type drift region 12 is a portion of the n⁻-type silicon carbide layer 42 in which a diffused region is not formed by ion implantation and the dopant concentration at the time of epitaxial growth is maintained. The n⁻-type drift region 12 is in contact with the n⁺-type starting substrate 41 and is provided from the active region to the chip end. The n⁻-type silicon carbide layer 42 may be formed by a single stage of epitaxial growth, and the p-type base region 13, n⁺-type source regions 14, p⁺⁺-type contact regions 15, an n-type current spreading region 20, p⁺-type regions 21, and p⁺-type connection regions 23 may be formed by ion implantation.

A trench gate structure is provided in the active region of the first embodiment. The trench gate structure includes a p-type base region (second semiconductor layer of the second conductivity type) 13, n⁺-type source regions (first semiconductor regions of the first conductivity type) 14, the p⁺⁺-type contact regions (second semiconductor region of the second conductivity type) 15, trenches 16, gate insulating films 17, and gate electrodes 18. The p-type base region 13, the n⁺-type source regions 14, and the p⁺⁺-type contact regions 15 are diffused regions formed in the n⁻-type silicon carbide layer 42 by ion implantation. The p-type base region 13 is provided in an entire area between the front surface of the semiconductor substrate 40 and the n⁻-type drift region 12.

The n⁺-type source regions 14 and the p⁺⁺-type contact regions 15 are each selectively provided between the front surface of the semiconductor substrate 40 and the p-type base region 13, and each have a bottom portion (lower surface, end facing the back surface of the semiconductor substrate 40) in contact with the p-type base region 13. The n⁺-type source regions 14 are provided in contact with the p⁺⁺-type contact regions 15. The n⁺-type source regions 14 and the p⁺⁺-type contact regions 15 each have an upper surface (the end facing the front surface of the semiconductor substrate 40) in ohmic contact with ohmic electrodes 43.

Between the n⁻-type drift region 12 and the p-type base region 13, the n-type current spreading region 20 and the p⁺-type regions (high-concentration regions of the second conductivity type) 21 are each selectively provided at deep positions closer to the n⁺-type drain region 11 (back surface of the semiconductor substrate 40) than are the bottoms of the trenches 16, and the p⁺-type connection regions (connection regions of the second conductivity type) 23 are selectively provided closer to the p-type base region 13 than are the bottoms of the trenches 16. The n⁻-type current spreading region 20, the p⁺-type regions 21, and the p⁺-type connection regions 23 are diffused regions formed in the n⁻-type silicon carbide layer 42 by ion implantation. Preferably, the n-type current spreading region 20 may reach a deep position closer to the n⁺-type drain region 11 than are the p⁺-type regions 21.

The n-type current spreading region 20 is a so-called current spreading layer (CSL) that reduces spreading resistance of carriers. The n-type current spreading region 20 is in contact with the p⁺-type regions 21 and the p⁺-type connection regions 23 between these regions, the n-type current spreading region 20 extends in a direction parallel to the front surface of the semiconductor substrate 40, reaches the trenches 16, and is in contact with the gate insulating films 17. The n-type current spreading region 20, at an upper surface thereof, is in contact with the p-type base region 13 and at a bottom thereof, is in contact with the n⁻-type drift region 12.

The n-type current spreading region 20 may be omitted. When the n-type current spreading region 20 is omitted, instead of the n-type current spreading region 20, the n⁻-type drift region 12 reaches the p-type base region 13 and is in contact with the p-type base region 13, the p⁺-type regions 21, and the p⁺-type connection regions 23. The n⁻-type drift region 12 is in contact with the gate insulating films 17 at portions of the sidewalls of the trenches 16.

The p⁺-type regions 21 and the p⁺-type connection regions 23 are fixed to a potential of a source electrode 44 described later, and have a function of relaxing electric field applied to the gate insulating films 17 by being depleted (and/or depleting the n-type current spreading region 20) when the MOSFET (silicon carbide semiconductor device 10) is off. The p⁺-type regions 21 are provided apart from the p-type base region 13 and respectively face the bottom surfaces of the trenches 16 in the depth direction. The p⁺-type regions 21 are electrically connected to the source electrode 44 by being partially coupled to the p⁺-type connection regions 23. FIG. 2A depicts a cross section of a portion where the p⁺-type connection regions 23 are provided and the p⁺-type regions 21 and the p⁺-type connection regions 23 are coupled to each other, and FIGS. 2B and 2C depict cross sections of portions where the p⁺-type connection regions 23 are not provided.

The p⁺-type regions 21 may be in contact with the gate insulating films 17 respectively at the bottoms of the trenches 16, or may be apart from the bottoms of the trenches 16. A width of each of the p⁺-type regions 21 is the same as or wider than a width of each of the trenches 16. For example, preferably, the width of the p⁺-type regions 21 may be twice the width of the trenches 16 or more. By making the width of the p⁺-type regions 21 wider than the width of the trenches 16, the p⁺-type regions 21 also face bottom corner portions (boundaries between the sidewalls and the bottom) of the trenches 16 in the depth direction. Thereby, the effect of relaxing the electric field in near the bottoms of the trenches 16 by the p⁺-type regions 21 is further enhanced. As depicted in FIG. 3C, the p⁺-type regions 21 are disposed in a striped pattern in a longitudinal direction of the trenches 16 in a plan view.

As depicted in FIG. 2A, the p⁺-type connection regions 23 are regions that connect the p⁺-type regions 21 and the p-type base region 13, and are formed at positions shallower than are the p⁺-type regions 21 (on the p-type base region 13 side) but deeper than is the p-type base region 13 (closer to the n⁺-type starting substrate). As depicted in FIG. 3B, the p⁺-type connection regions 23 are disposed in a linear shape between the trenches 16, extending in a direction orthogonal to the longitudinal direction of the trenches 16 (lateral direction of the trenches 16) in a plan view, and are in contact with the trenches 16. By forming the p⁺-type connection regions 23 in a linear shape between the trenches 16, the contact area between the p⁺-type connection regions 23 and the p⁺-type regions 21 below the trenches 16 increases, and the breakdown voltage may be improved. In addition, as depicted in FIG. 3A, the p⁺⁺-type contact regions 15 are periodically disposed in the longitudinal direction of the trenches 16 in a dot-like shape between the trenches 16 in a plan view, and are apart from the trenches 16. By forming the p⁺⁺-type contact regions 15 in dot-like shapes, the characteristics of the silicon carbide semiconductor device 10 may be improved.

As depicted in FIGS. 3A and 3B, the p⁺-type connection regions 23 are disposed in a region that does not overlap the p⁺⁺-type contact regions 15 in a plan view. Thus, a region having the p⁺-type connection regions 23 but free of the p⁺⁺-type contact regions 15 as depicted in FIG. 2A, a region free of the p⁺-type connection regions 23 and the p⁺⁺-type contact regions 15 as depicted in FIG. 2B, and a region having the p⁺⁺-type contact regions 15 but free of the p⁺-type connection regions 23 as depicted in FIG. 2C are periodically arranged in the longitudinal direction of the trenches 16.

The width of each of the p⁺-type connection regions 23 in the direction orthogonal to the longitudinal direction of (the lateral direction) the trenches 16 in a plan view may preferably wider than the width of each of the p⁺⁺-type contact regions 15 in the direction orthogonal to the longitudinal direction of the trenches 16. As described, the contact area between the p⁺-type connection regions 23 and the p⁺-type regions 21 below the trenches 16 increases, and the breakdown voltage may be improved.

As described, by providing the p⁺-type connection regions 23 that are shallower than are the p⁺-type regions 21 below the trenches 16 and deeper than is the p-type base region 13, it is possible to increase the area for connecting the p⁺-type regions 21 and the p⁺⁺-type contact regions 15. This makes it possible to suppress fluctuation of feedback capacitance and reduce SW loss. Furthermore, since the p⁺-type connection regions 23 reduce the area of the p-type base region 13 exposed on the side thereof facing the drain electrode 45, a high voltage is less likely to be applied to the p-type base region 13, and the breakdown voltage may be increased.

As described, by providing the p⁺-type connection regions 23, while it is possible to shorten the cell pitch and realize a high breakdown voltage and a low channel resistance, the drift resistance does not change. In one known super junction (SJ) structure, a drift layer is a parallel pn layer in which n-type column regions and p-type column regions are arranged adjacent to each other, repeatedly alternating with each other in a direction parallel to a main surface of the substrate. In the SJ structure, by making the dopant concentrations contained in the p-type column regions and the n-type column regions substantially equal to each other, it is possible to artificially create a non-doped layer in the off state and achieve a high breakdown voltage.

Therefore, in the first embodiment, the n⁻-type drift region 12 and the n-type current spreading region 20 have an SJ structure in which p-type regions (p-type column regions 24) and n-type regions (portions of the n⁻-type drift region 12 and the n-type current spreading region 20 sandwiched between the p-type column regions 24, hereinafter referred to as n-type column regions 25) extending in a direction perpendicular to the substrate main surface and having a narrow width in a plane parallel to the substrate main surface are and repeatedly arranged alternating each other in a plane parallel to the substrate main surface (hereinafter referred to as a pn parallel region 26). The p-type column regions (second column regions of the second conductivity type) 24 and the n-type column regions (first column regions of the first conductivity type) 25 constituting the pn parallel region 26 are regions having an increased dopant concentration relative to the n⁻-type drift region 12. FIGS. 1 to 2D depict a semi-SJ structure in which the p-type column regions 24 and the n-type column regions 25 are provided so as not to reach the surface of the n⁺-type drain region 11. However, a full-SJ structure in which the p-type column regions 24 and the n-type column regions 25 reach the surface of the n⁺-type drain region 11 may be employed. FIG. 3D is a plan view depicting the structure of the pn parallel region 26.

As for a charge balance of the pn parallel region 26, a product (dopant amount) of the width of each of the p-type column regions 24 and a dopant concentration of the p-type column regions 24 is substantially equal to a product (dopant amount) of the width of each of the n-type column regions 25 and a dopant concentration of the n-type column regions 25. Specifically, a difference between the dopant amount of the p-type column regions 24 and the dopant amount of the n-type column regions 25 is set to be within ±5%. Therefore, in the pn parallel region 26, a pseudo non-doped layer may be created in the off state to increase the breakdown voltage, and both characteristics of low on-resistance and high breakdown voltage may be obtained at the same time. Thus, the dopant concentration of the n⁻-type drift region 12 may be increased, the thickness of the n⁻-type drift region 12 may be decreased, and the drift resistance may be reduced.

The charge balance of the pn parallel region 26 is preferably p-rich in which the amount of p-type dopant is larger than the amount of n-type dopant. By making the charge balance p-rich, avalanche tolerance may be increased. Further, since the activation rate of the p-type dopant is low in the p-type layer, the charge balance of the pn parallel region 26 may be easily obtained by designing the p-type layer to be p-rich in advance.

As depicted in FIGS. 1 to 2C, in the first embodiment, the p-type column regions 24 are provided below the p⁺-type regions 21 so as to be in contact with the p⁺-type regions 21. Further, as depicted in FIGS. 2A to 2C, while the p-type column regions 24 have substantially the same width as the p⁺-type regions 21, the p-type column regions 24 may be narrower than the p⁺-type regions 21. FIG. 2D is a cross-sectional view taken along line C-C′ in FIG. 1 when the p-type column regions 24 are narrower than the p⁺-type regions 21. While not depicted, the same applies to the cross-sectional view along cutting line A-A′ in FIG. 1 and the cross-sectional view along cutting line B-B′ in FIG. 1. By making the p-type column regions 24 narrower than the p⁺-type regions 21, even when the formation position of the p-type column regions 24 is displaced, the upper surfaces of the p-type column regions 24 come into contact with the p⁺-type regions 21, and the tolerance to the displacement of the p-type column regions 24 may be increased.

While not depicted, the pn parallel region 26 is provided spanning the entire chip. Therefore, the pn parallel region 26 is also provided in the edge termination region. In the edge termination region, the p-type base region 13 is not provided at the surface, and a guard ring is provided as a voltage withstanding structure above the n-type column region 25 of the pn parallel region 26.

Preferably, the dopant concentration of the p⁺-type connection regions 23 may be higher than the dopant concentration of the p-type base region 13 and lower than the dopant concentration of the p⁺-type regions 21. The dopant concentration of the p⁺⁺-type contact regions 15 is 1×10²⁰/cm³ or more and is higher than the dopant concentrations of the p-type base region 13, the p⁺-type connection regions 23, the p-type column regions 24, and the p⁺-type regions 21. Preferably, the dopant concentrations of the p-type base region 13, the p⁺-type connection regions 23, and the p⁺-type regions 21 may be 9.0×10¹⁶/cm³ or more. More preferably, the p⁺-type connection regions 23 and the p⁺-type regions 21 have a same dopant concentration on the order of 1×10¹⁸/cm³. The p-type column regions 24 have a dopant concentration equal to or lower than those of the p⁺-type connection regions 23 and the p⁺-type regions 21, and preferably may be 9.0×10¹⁶/cm³ or more but not more than 1×10¹⁸/cm³.

The trenches 16 penetrate through the n⁺-type source regions 14 and the p-type base region 13 in the depth direction and reach the n-type current spreading region 20 (the n⁻-type drift region 12 when the n-type current spreading region 20 is not provided). The trenches 16 may terminate in the p⁺-typeregions 21. For example, the trenches 16 extend in a linear shape in a direction parallel to the front surface of the semiconductor substrate 40 and reach an outer peripheral portion (not depicted) of the active region. The gate electrodes 18 are provided in the trenches 16 via the gate insulating films 17.

The interlayer insulating film 19 is provided on the front surface of the semiconductor substrate 40, and particularly covers the gate electrodes 18. The ohmic electrodes (first electrodes) 43 are provided on portions of the front surface of the semiconductor substrate 40 exposed in contact holes of the interlayer insulating film 19. The ohmic electrodes 43 are in ohmic contact with the n⁺-type source regions 14 and the p⁺⁺-type contact regions 15 at the front surface of the semiconductor substrate 40, in the contact holes of the interlayer insulating film 19. The ohmic electrodes 43 are constituted by, for example, a nickel silicide film (NixSiy, x and y are arbitrary integers). Instead of the nickel silicide film, the surfaces of the n⁺-type source regions 14 and the p⁺⁺-type contact regions 15 may be brought into ohmic contact as a 3C structure of cubic 3 C-SiC.

The source electrode (the ohmic electrodes 43 and the source electrode are collectively referred to as first electrodes) 44 is provided covering the interlayer insulating film 19 so as to be embedded in the contact holes of the interlayer insulating film 19. The source electrode 44 is provided in substantially an entire central area of the active region. The source electrode 44 is electrically connected to the n⁺-type source regions 14, the p⁺⁺-type contact regions 15, the p-type base region 13, the p+-type regions 21, and the p+-type connection regions 23 via the ohmic electrodes 43.

A barrier metal 38 for preventing diffusion of metal atoms toward the gate electrodes 18 may be provided on the ohmic electrodes 43 and the interlayer insulating film 19. The barrier metal 38 contains, for example, titanium (Ti) or titanium nitride (TiN). The barrier metal 38 may have a two-layer structure of Ti and TiN with Ti being relatively closer to the semiconductor substrate 40. In this case, the source electrode 44 is provided on the barrier metal 38.

The drain electrode (second electrode) 45 is provided in an entire area of the back surface of the semiconductor substrate 40 (back surface of the n⁺-type starting substrate 41), is in ohmic contact with the n⁺-type drain region 11 (the n⁺-type starting substrate 41), and is electrically connected to the n⁺-type drain region 11.

Next, a method of manufacturing the silicon carbide semiconductor device according to the first embodiment will be described. The silicon carbide semiconductor device according to the first embodiment is manufactured in the same manner as the method for manufacturing the silicon carbide semiconductor device of the comparative example. For example, the silicon carbide semiconductor device according to the first embodiment is manufactured as follows. First, a first n⁻-type silicon carbide layer to be the n⁻-type drift region 12 is grown by epitaxy on the front surface of the n⁺-type starting substrate (n⁺-type starting wafer) 41.

Next, the p-type column regions 24 in the n⁻-type drift region 12 are formed from the surface of the n⁻-type drift region 12 by photolithography and ion implantation of a p-type dopant. Next, a second n⁻-type silicon carbide layer to be a lower portion of the n-type current spreading region 20 is grown by epitaxy on the front surface of the n⁻-type drift region 12. Next, the p-type column regions 24 in the second n⁻-type silicon carbide layer are formed by photolithography and ion implantation of a p-type dopant from the surface of the second n⁻-type silicon carbide layer. Next, a lower portion of the n-type current spreading region 20 is formed in the second n⁻-type silicon carbide layer by ion implantation of an n-type dopant. Here, the p-type column regions 24 are formed by ion implantation. However, the p-type column regions 24 may be formed by forming trenches that extend to the n⁻-type drift region 12 from the surface of the second n⁻-type silicon carbide layer and then, embedding the trenches with a p-type dopant by epitaxial growth.

Next, on the front surface of the second n⁻-type silicon carbide layer, a third n⁻-type silicon carbide layer to be a middle portion of the n-type current spreading region 20 is grown by epitaxy. Next, the p⁺-type regions 21 are selectively formed in the third n⁻-type silicon carbide layer by photolithography and ion implantation of a p-type dopant. Next, the middle portion of the n-type current spreading region 20 is formed in the third n⁻-type silicon carbide layer by ion implantation of an n-type dopant.

Next, a fourth n⁻-type silicon carbide layer is grown by epitaxy on the middle portion of the n-type current spreading region 20. Next, an upper portion of the n-type current spreading region 20 is formed in the fourth n⁻-type silicon carbide layer by ion implantation of an n-type dopant. Next, the fifth n⁻-type silicon carbide layer is grown by epitaxy on the fourth n⁻-type silicon carbide layer. By the processes described above, the semiconductor substrate (semiconductor wafer) 40 having a predetermined thickness in which the n⁻-type silicon carbide layer 42 is stacked on the n⁺-type starting substrate 41 is completed.

Next, the p-type base region 13 is formed in the fifth n⁻-type silicon carbide layer by photolithography and ion implantation of a p-type dopant. Next, the n⁺-type source regions 14 are selectively formed in the fifth n⁻-type silicon carbide layer, at the surface thereof by photolithography and ion implantation of an n-type dopant.

Next, by photolithography and ion implantation of a p-type dopant, the p⁺-type connection regions 23 are formed in the fourth n⁻-type silicon carbide layer such that the lower surfaces of the p⁺-type connection regions 23 are in contact with the p⁺-type regions 21 and the upper surfaces thereof are in contact with the p-type base region 13. Next, the p⁺⁺-type contact regions 15 are selectively formed in the fifth n⁻-type silicon carbide layer, at the surface thereof by photolithography and ion implantation of a p-type dopant.

A portion of the n⁻-type silicon carbide layer 42 that is free of ion implantation and remains at the dopant concentration at the time of epitaxial growth constitutes the n⁻-type drift region 12. Next, a heat treatment for activating the dopants ion-implanted in the n⁻-type silicon carbide layer 42 is performed. The heat treatment for activating the dopants may be performed each time the dopants are ion-implanted into the first to fifth n⁻-type silicon carbide layers, or may be performed for the dopants collectively. Next, the trenches 16, the gate insulating films 17, and the gate electrodes 18 are formed by a general method.

Next, the interlayer insulating film 19 is formed on the front surface of the semiconductor substrate 40. Next, the source electrode 44, a gate pad (not depicted), a passivation film (surface protective film: not depicted), and the drain electrode 45 are formed by a general method. A portion of the source electrode 44 exposed in the opening of the passivation film serves as a source pad. Thereafter, the semiconductor wafer is diced (cut) into individual chips, thereby completing silicon carbide semiconductor device 10 depicted in FIGS. 1 to 3D.

As described above, according to the silicon carbide semiconductor device of the first embodiment, the p⁺-type connection regions shallower than the p⁺-type regions below the trench and deeper than the p-type base region are provided. As a result, the area for connecting the p⁺-type regions and the p⁺⁺-type contact regions may be increased, variation in feedback capacitance may be suppressed, and SW loss may be reduced. Furthermore, since the p⁺-type connection regions reduce the region where the p-type base region is exposed on the side thereof facing the drain electrode, a high voltage is less likely to be applied to the p-type base region, and the breakdown voltage may be increased. Further, a pn parallel region having an SJ structure is formed below the p⁺-type regions below the trenches. As a result, the dopant concentration of the n⁻-type drift region may be increased and the thickness of the n⁻-type drift region may be decreased, thereby reducing the drift resistance.

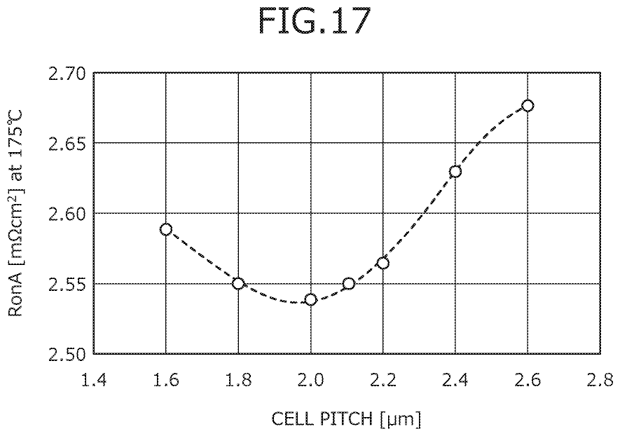

The on-resistance of the silicon carbide semiconductor device of the first embodiment was simulated by changing the cell pitch. FIG. 17 is a characteristic diagram depicting a relationship between the cell pitch and the on-resistance of the silicon carbide semiconductor device according to the first embodiment. In FIG. 17, the dopant concentration of each of the p-type column regions 24 and the n⁻-type column regions 25 was 9.5×10¹⁶/cm³, and the depth thereof was 1.5 μm. The on-resistance (RonA) was examined by changing the periodic repetition pitch (equivalent to the cell pitch) of the p-type column regions 24 and the n-type column regions 25 from 1.6 μm to 2.6 μm. The threshold value (Vth) was set to 4 V. Favorable on-resistances of 2.54 mΩcm² to 2.56 mΩcm² were obtained when the cell pitch was 1.8 μm to 2.2 μm. In each case, a breakdown voltage of 1500 V or more, which is sufficient for a device of a 1200 V breakdown voltage class, was obtained.

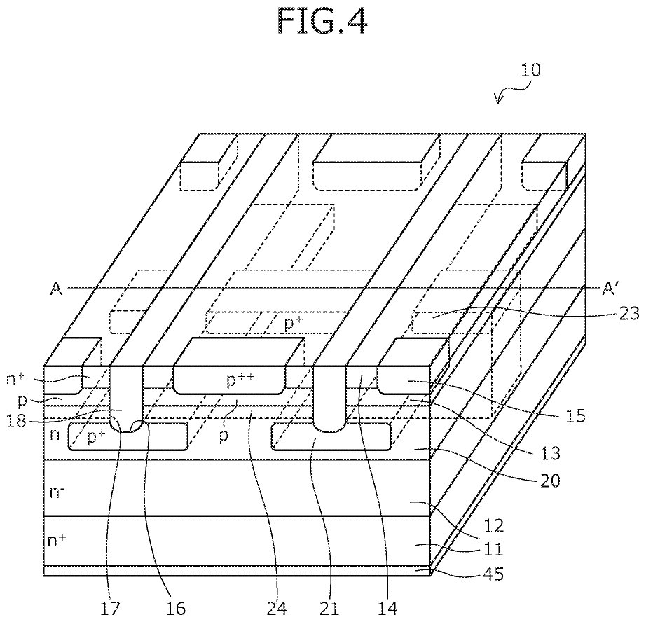

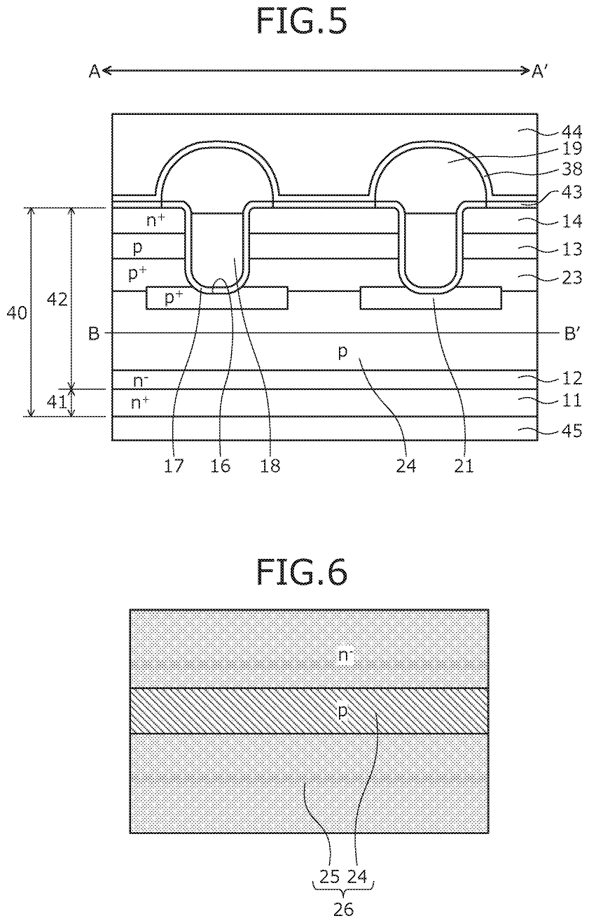

Next, a structure of a silicon carbide semiconductor device according to a second embodiment will be described. FIG. 4 is a perspective view depicting a structure of a silicon carbide semiconductor device according to a second embodiment. FIG. 5 is a cross-sectional view depicting the structure of the silicon carbide semiconductor device according to the second embodiment, along cutting line A-A′ in FIG. 4. FIG. 6 is a plan view depicting the structure of the silicon carbide semiconductor device according to the second embodiment, along cutting line B-B′ in FIG. 5.

The silicon carbide semiconductor device 10 according to the second embodiment differs from the silicon carbide semiconductor device 10 according to the first embodiment in that the p-type column regions 24 are provided below the p⁺-type connection regions 23 so as to be in contact with the p⁺-type connection regions 23. As depicted in FIG. 4, while a width (width in the longitudinal direction of the trenches 16) of each of the p-type column regions 24 is substantially equal to that of the p⁺-type connection regions 23, the p-type column regions 24 may be narrower than the p⁺-type connection regions 23.

In addition, since no channel is formed where the p⁺-type connection regions 23 are provided, by providing the p-type column regions 24 below the p⁺-type connection regions 23, the p-type column regions 24 do not become a resistor, and the JFET resistance (spreading resistance) may be reduced.

As described above, according to the silicon carbide semiconductor device of the second embodiment, the p⁺-type connection regions are provided as in the first embodiment. As a result, similar to the first embodiment, the variation of the feedback capacitance may be suppressed, the SW loss may be reduced, and the breakdown voltage may be increased. In the second embodiment, the pn parallel region having the SJ structure is formed below the p⁺-type connection regions. Thus, as in the first embodiment, the dopant concentration of the n⁻-type drift region may be increased and the thickness of the n⁻-type drift region may be reduced, and the drift resistance may be decreased.

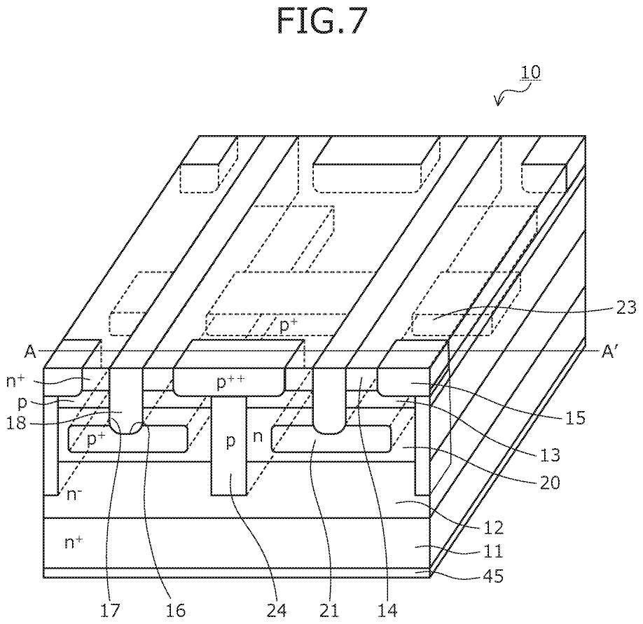

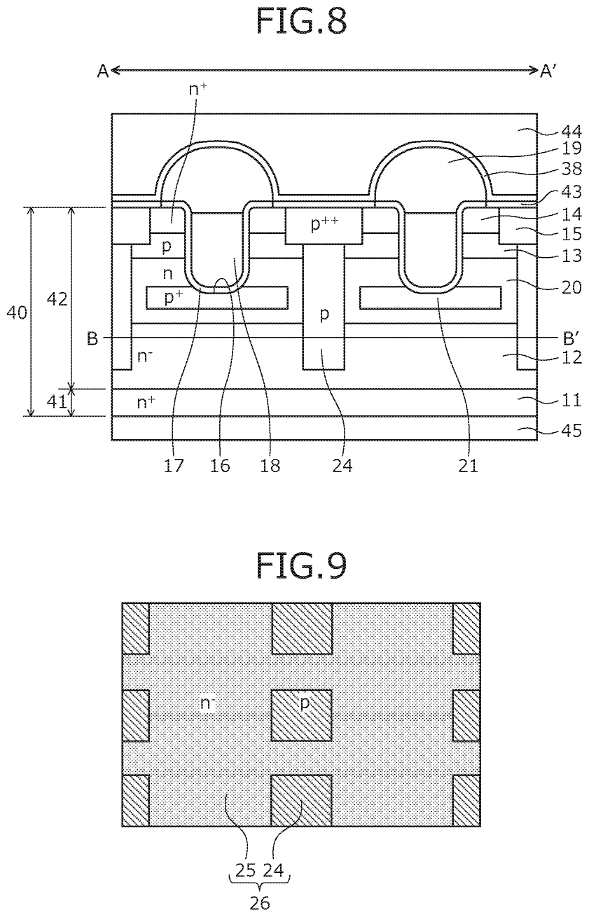

Next, a structure of a silicon carbide semiconductor device according to a third embodiment will be described. FIG. 7 is a perspective view depicting a structure of a silicon carbide semiconductor device according to a third embodiment. FIG. 8 is a cross-sectional view depicting the structure of the silicon carbide semiconductor device according to the third embodiment, along cutting line A-A′ in FIG. 7. FIG. 9 is a plan view depicting the structure of the silicon carbide semiconductor device according to the third embodiment, along cutting line B-B′ in FIG. 8.

The silicon carbide semiconductor device 10 according to the third embodiment differs from the silicon carbide semiconductor device 10 according to the first embodiment in that the p-type column regions 24 are provided below the p⁺⁺-type contact regions 15 so as to be in contact with the p⁺⁺-type contact regions 15. In addition, in FIGS. 7 and 8, while the p-type column regions 24 are narrower than the p⁺⁺-type contact regions 15, the width of the p⁺⁺-type contact regions 15 may be decreased, and the p-type column regions 24 may have the same width as that of the p⁺⁺-type contact regions 15.

As depicted in FIG. 7, the p⁺⁺-type contact regions 15 are provided so as to be dispersed in the longitudinal direction of the trenches 16. Thus, the p-type column regions 24 are also provided to be dispersed in the longitudinal direction of the trenches 16. As a result, the current path is shortened, and the avalanche tolerance may be increased.

As described above, according to the silicon carbide semiconductor device of the third embodiment, the p⁺-type connection regions are provided as in the first embodiment. As a result, similar to the first embodiment, variation of the feedback capacitance may be suppressed, the SW loss may be reduced, and the breakdown voltage may be increased. In the third embodiment, the pn parallel region having the SJ structure is formed below the p⁺⁺-type contact regions. Thus, as in the first embodiment, the dopant concentration of the n⁻-type drift region may be increased and the thickness of the n⁻-type drift region may be reduced, and the drift resistance may be decreased.

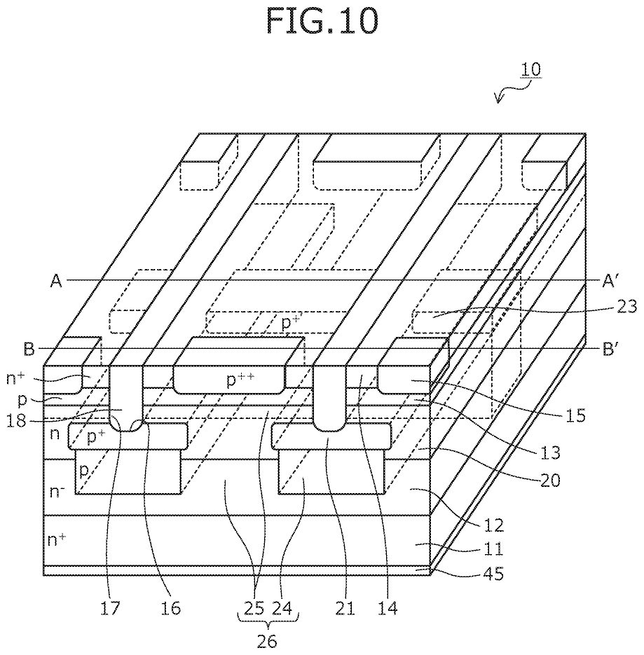

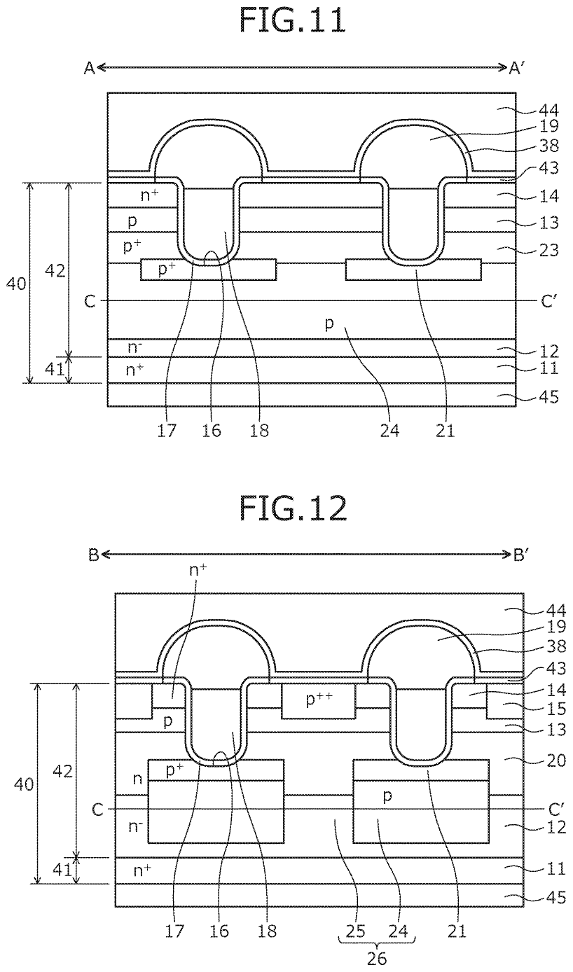

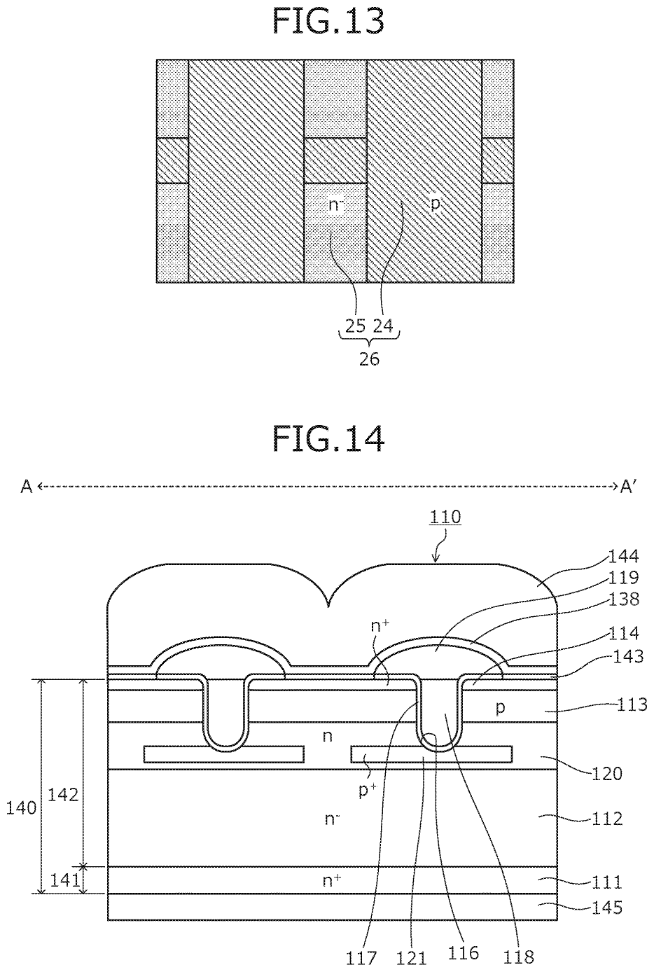

Next, a structure of a silicon carbide semiconductor device according to a fourth embodiment will be described. FIG. 10 is a perspective view depicting a structure of a silicon carbide semiconductor device according to a fourth embodiment. FIG. 11 is a cross-sectional view of the structure of the silicon carbide semiconductor device according to the fourth embodiment, along cutting line A-A′ in FIG. 10. FIG. 12 is a cross-sectional view of the structure of the silicon carbide semiconductor device according to the fourth embodiment, along cutting line B-B′ in FIG. 10. FIG. 13 is a plan view depicting the structure of the silicon carbide semiconductor device according to the fourth embodiment, along cutting line C-C′ depicted in FIGS. 11 and 12.

The silicon carbide semiconductor device 10 according to the fourth embodiment differs from the silicon carbide semiconductor device 10 according to the first embodiment in that the p-type column regions 24 are provided below the p⁺-type regions 21 and the p⁺-type connection regions 23 below the trenches so as to be in contact with the p⁺-type regions 21 and the p⁺-type connection regions 23 below the trench. Further, in FIGS. 10 and 12, while the p-type column regions 24 have substantially the same width as that of the p⁺-type regions 21, the p-type column regions 24 may be narrower than the p⁺-type regions 21. Further, in FIG. 10, while the p-type column regions 24 have substantially the same width (width in the longitudinal direction of the trenches 16) as the p⁺-type connection regions 23, the p-type column regions 24 may be narrower than the p⁺-type connection regions 23.

In the fourth embodiment, as depicted in FIG. 13, the p-type column regions 24 surround the n-type column regions 25 in a plan view. Thus, the dopant concentration of the p-type column regions 24 may be increased, and at the same time, the dopant concentration of the n-type column region 25 may be increased. As a result, the resistance of the pn parallel regions 26 is reduced, and the effect of the SJ structure may be enhanced as compared with the first to third embodiments.

As described above, according to the silicon carbide semiconductor device of the fourth embodiment, the p⁺-type connection regions are provided as in the first embodiment. As a result, similar to the first embodiment, variation of the feedback capacitance may be suppressed, the SW loss may be reduced, and the breakdown voltage may be increased. In the fourth embodiment, the pn parallel region having the SJ structure is formed below the p⁺-type regions and the p⁺-type connection regions. Thus, as in the first embodiment, the dopant concentration of the n⁻-type drift region may be increased and the thickness of the n⁻-type drift region may be decreased, and the drift resistance may be reduced.

In the fourth embodiment, while the pn parallel region 26 is formed below the p⁺-type regions 21 and the p⁺-type connection regions 23, a combination other than this is also possible. For example, the pn parallel region 26 may be formed below the p⁺⁺-type contact regions 15 and the p⁺-type connection regions 23, the pn parallel region 26 may be formed below the p⁺⁺-type contact regions 15 and the p⁺-type regions 21, and the pn parallel region 26 may be formed below the p⁺⁺-type contact regions 15, the p⁺-type connection regions 23, and the p⁺-type regions 21.

In the above description, the present disclosure may be variously modified within a range not departing from the spirit of the present disclosure, and in each of the embodiments described above, for example, dimensions, dopant concentrations, and the like of each region are variously set according to necessary specifications and the like. Further, in each of the above-described embodiments, while a MOSFET having a trench structure has been described as an example, the present disclosure is further applicable to other semiconductor devices having a trench structure such as IGBTs and the like.

According to the above disclosure, the p⁺-type connection regions (connection regions) that are shallower than the p⁺-type regions (high-concentration regions) below the trenches and deeper than the p-type base region (second semiconductor layer) are provided. As a result, the area for connecting the p⁺-type regions and the p⁺⁺-type contact regions may be increased, variation in feedback capacitance may be suppressed, and SW loss may be reduced. Furthermore, since the p⁺-type connection regions reduce the areas where the p-type base region is exposed on the side thereof facing the drain electrode, a high voltage is less likely to be applied to the p-type base region, and the breakdown voltage may be increased. Further, a pn parallel region having an SJ structure is formed below the p⁺-type regions below the trenches. As a result, the dopant concentration of the n⁻-type drift region (first semiconductor layer) may be increased and the thickness of the n⁻-type drift region may be reduced, thereby reducing the drift resistance.

According to the silicon carbide semiconductor device of the present disclosure, the cell pitch may be shortened, a high breakdown voltage and a low resistance may be realized, and the drift resistance may be reduced.

As described above, the silicon carbide semiconductor device according to the present disclosure is useful for power semiconductor devices used in power converting equipment such as inverters, power supply devices of various industrial machines, igniters of automobiles, or the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

1. A semiconductor device, comprising:
a silicon carbide semiconductor substrate of a first conductivity type, having a front surface and a back surface;
a first semiconductor layer of the first conductivity type, provided on the front surface of the silicon carbide semiconductor substrate and having a dopant concentration lower than a dopant concentration of the silicon carbide semiconductor substrate, the first semiconductor layer having a first surface and a second surface opposite to each other, the second surface facing the silicon carbide semiconductor substrate;
a pn parallel region provided at the first surface of the first semiconductor layer, and having a plurality of first column regions of the first conductivity type and a plurality of second column regions of a second conductivity type disposed repeatedly alternating with each other in a plane parallel to the front surface of the silicon carbide semiconductor substrate;
a second semiconductor layer of a second conductivity type, provided at the first surface of the first semiconductor layer and having a first surface and a second surface opposite to each other, the second surface thereof facing the silicon carbide semiconductor substrate;
a plurality of first semiconductor regions of the first conductivity type, selectively provided in the second semiconductor layer, at the first surface thereof;
a plurality of second semiconductor regions of the second conductivity type, selectively provided in the second semiconductor layer, at the first surface thereof, in contact with the plurality of first semiconductor regions and the second semiconductor layer;
a plurality of trenches penetrating through the plurality of first semiconductor regions, respectively, and the second semiconductor layer, and reaching the first semiconductor layer;
a plurality of gate insulating films, respectively, provided in the plurality of trenches;
a plurality of gate electrodes, respectively, provided in the plurality of trenches via the plurality of gate insulating films;
a plurality of high-concentration regions of the second conductivity type, provided in the first semiconductor layer, respectively, at positions facing the plurality of trenches in a depth direction of the semiconductor device;
a plurality of connection regions of the second conductivity type, selectively provided in the first semiconductor layer, the plurality of connection regions being closer to the second semiconductor layer than are the plurality of high-concentration regions, and being closer to the silicon carbide semiconductor substrate than is the second semiconductor layer, the plurality of connection regions being in contact with the plurality of high-concentration regions and the second semiconductor layer;
a plurality of first electrodes provided at surfaces of the plurality of the first semiconductor regions and the plurality of second semiconductor regions;
a second electrode provided at the back surface of the silicon carbide semiconductor substrate, wherein
the plurality of second semiconductor regions is disposed periodically in a longitudinal direction of the plurality of trenches, and
the plurality of connection regions is disposed periodically in the longitudinal direction of the plurality of trenches, in regions not overlapping the plurality of second semiconductor regions in a plan view of the semiconductor device.

2. The silicon carbide semiconductor device according to claim 1, wherein the plurality of second column regions is provided closer to the silicon carbide semiconductor substrate than is the plurality of high-concentration regions, and is in contact with surfaces of the plurality of high-concentration regions facing the silicon carbide semiconductor substrate.

3. The silicon carbide semiconductor device according to claim 1, wherein the plurality of second column regions is closer to the silicon carbide semiconductor substrate than is the plurality of connection regions, and is in contact with surfaces of the plurality of connection regions facing the silicon carbide semiconductor substrate.

4. The silicon carbide semiconductor device according to claim 1, wherein the plurality of second column regions is closer to the silicon carbide semiconductor substrate than is the plurality of second semiconductor regions and is in contact with surfaces of the plurality of second semiconductor regions facing the silicon carbide semiconductor substrate.

5. The silicon carbide semiconductor device according to claim 1, wherein the plurality of second column regions is closer to the silicon carbide semiconductor substrate than are the plurality of high-concentration regions and the plurality of connection regions, and in contact with surfaces of the plurality of high-concentration regions and the plurality of connection regions facing the silicon carbide semiconductor substrate.

6. The silicon carbide semiconductor device according to claim 2, further includes a region of the second conductivity type underneath each of the plurality of trenches, wherein each of the plurality of second column regions has a first surface and a second surface opposite to each other, the first surface thereof being in contact with the region and the second surface thereof facing the silicon carbide semiconductor substrate, a width of each of the plurality of second column regions being a same as a width of said region.

7. The silicon carbide semiconductor device according to claim 2, further includes a region of the second conductivity type underneath each of the plurality of trenches, wherein each of the plurality of second column regions has a first surface and a second surface opposite to each other, the first surface thereof being in contact with the region and the second surface thereof facing the silicon carbide semiconductor substrate, a width of each of the plurality of second column regions being narrower than a width of said region.

8. The silicon carbide semiconductor device according to claim 1, wherein a periodic repetition pitch of the plurality of first column regions and the plurality of second column regions is 1.8 μm or more but not more than 2.2 μm.
